(19) United States
(12) Patent Application Publication
(10) Pub. No.: US 2026/0246252 A1
(43) Pub. Date: Aug. 20, 2026

(54) ELECTRICAL JUNCTION BOX

(71) Applicant: Sumitomo Wiring Systems, Ltd., Yokkaichi-shi (JP)

(72) Inventor: Naoki HASHIMOTO, Yokkaichi-shi (JP)

(73) Assignee: Sumitomo Wiring Systems, Ltd., Yokkaichi-shi (JP)

(21) Appl. No.: 19/538,534

(22) Filed: Feb. 12, 2026

(30) Foreign Application Priority Data
Feb. 19, 2025 (JP) 2025-024676

(51) Int. Cl. H02G 3/08

(52) U.S. Cl. CPC H02G 3/088

(57) ABSTRACT

The electrical junction box includes a case configured to accommodate a substrate on which an electronic component is mounted. The case has, on a surface thereof opposite to a surface thereof opposing the substrate, a back surface facing an attachment surface. The case has, in a vertical orientation in which the back surface is disposed along an up-down direction, left and right side walls protruding from positions of the back surface that are spaced apart in a left-right direction and extending from upper ends thereof toward lower ends thereof. A water receiving port that is open above the back surface is provided between the upper ends of the left and right side walls. A drainage port that is open below the back surface is provided between the lower ends of the left and right side walls.

### CROSS-REFERENCE TO RELATED APPLICATIONS

This application claims priority of Japanese Patent Application No. JP 2025-024676 filed on February 19, 2025, the content of which is incorporated herein.

### TECHNICAL FIELD

The present disclosure relates to an electrical junction box.

### BACKGROUND

JP 2024-176198A discloses an electrical junction box (referred to as an electronic substrate unit in JP 2024-176198A) including an upper cover and a lower cover, and configured to accommodate therein a substrate on which electronic components are mounted.

JP 2024-176198A is an example of related art.

### SUMMARY

As a usage mode of JP 2024-176198A, it is also possible to envisage a mode in which a back surface of the lower cover is disposed in a vertical orientation along the up-down direction so as to oppose an attachment surface of a vehicle, and the electrical junction box is attached to the attachment surface in that state. When an electrical junction box in such a mode is placed in a wetting environment, there is a possibility that water may enter the boundary between the back surface of the lower cover and the attachment surface of the vehicle. If the entered water is not promptly discharged from the boundary, there is a concern that the lower cover may corrode. Moreover, there is also a problem of increased likelihood of entry of water into the case, for example.

Therefore, an object of the present disclosure is to provide an electrical junction box capable of promptly discharging water that has entered a space between a back surface of a case and an attachment surface.

An electrical junction box according to the present disclosure is an electrical junction box including: a case configured to accommodate a substrate on which an electronic component is mounted, wherein the case has, on a surface thereof opposite to a surface thereof opposing the substrate, a back surface facing an attachment surface, the case has, in a vertical orientation in which the back surface is disposed along an up-down direction, left and right side walls protruding from positions of the back surface that are spaced apart in a left-right direction and extending from upper ends thereof toward lower ends thereof, a water receiving port that is open above the back surface is provided between the upper ends of the left and right side walls, and a drainage port that is open below the back surface is provided between the lower ends of the left and right side walls.

According to the present disclosure, it is possible to provide an electrical junction box capable of promptly discharging water that has entered a space between a back surface of a case and an attachment surface.

### BRIEF DESCRIPTION OF THE DRAWINGS

FIG. 1 is a rear view of an electrical junction box according to Embodiment 1;

FIG. 2 is a cross-sectional view of the electrical junction box according to Embodiment 1, taken along the line A-A in FIG. 1;

FIG. 3 is an exploded perspective view of the electrical junction box according to Embodiment 1;

FIG. 4 is a bottom view of the electrical junction box according to Embodiment 1;

FIG. 5 is an enlarged perspective view of a drainage guide portion and peripheral portions thereof of the electrical junction box according to Embodiment 1; and

FIG. 6 is an enlarged perspective view of an upper end inclined surface portion and peripheral portions thereof of the electrical junction box according to Embodiment 1.

### DETAILED DESCRIPTION OF PREFERRED EMBODIMENTS

First, embodiments of the present disclosure will be listed and described.

An electrical junction box according to the present disclosure includes:

(1) a case configured to accommodate a substrate on which an electronic component is mounted, wherein the case has, on a surface thereof opposite to a surface thereof opposing the substrate, a back surface facing an attachment surface, the case has, in a vertical orientation in which the back surface is disposed along an up-down direction, left and right side walls protruding from positions of the back surface that are spaced apart in a left-right direction and extending from upper ends thereof toward lower ends thereof, a water receiving port that is open above the back surface is provided between the upper ends of the left and right side walls, and a drainage port that is open below the back surface is provided between the lower ends of the left and right side walls.

When the case is attached to the attachment surface in the vertical orientation, the drainage space is formed between the back surface of the case and the attachment surface by the left and side walls interposed between the two surfaces. Even if water enters a space between the back surface of the case and the attachment surface from the water receiving port, the entered water can be promptly discharged below the case from the drainage space through the drainage port. Accordingly, it is possible to avoid situations where a problem occurs as a result of water residing between the back surface of the case and the attachment surface.

(2) In the electrical junction box according to (1) above, it is preferable that the case has a lower wall protruding from a position near a lower end of the back surface and extending in a direction intersecting an extension direction of the left and right side walls, and the lower wall includes an inclined portion that is inclined downward toward the drainage port.

With the configuration according to (2) above, water that has entered the space between the back surface of the case and the attachment surface falls on the drainage space to come into contact with the lower wall, and is further guided to the drainage port along the inclined portion of the lower wall. Accordingly, it is possible to prevent water from remaining at positions near the lower end of the back surface.

(3) In the electrical junction box according to (1) or (2) above, it is preferable that the case includes a first case having the back surface, and a second case configured to be fixed to the first case, the second case includes a peripheral surface portion configured to cover an outer periphery of the first case, and the drainage port is provided at a drainage guide portion extending below the peripheral surface portion, across a boundary between a lower end of the first case and the peripheral surface portion.

Since the water in the drainage port can flow along the drainage guide portion, it is possible to prevent situations where water enters the interior of the case from the boundary between the lower end of the first case and the peripheral surface portion.

(4) In the electrical junction box according to any one of (1) to (3) above, it is preferable that the case includes a first case having the back surface, and a second case configured to be fixed to the first case via a fixing member, and the first case has a countersunk hole that is open in the back surface to accommodate a head portion of the fixing member, and a tube portion protruding from an outer periphery of the countersunk hole in the back surface.

Water that has entered the space between the back surface of the first case and the attachment surface can flow down while coming into contact with the tube portion and flowing around the tube portion. Accordingly, it is possible to avoid situations where the head portion of the fixing member is wetted.

(5) In the electrical junction box according to (2) above, it is preferable that the case includes a first case having the back surface, and a second case configured to be fixed to the first case via a fixing member, the first case has a countersunk hole that is open in the back surface to accommodate a head portion of the fixing member, and a tube portion protruding from an outer periphery of the countersunk hole in the back surface, and the tube portion is located between a lower end of the back surface of the first case and the inclined portion, and is coupled to the inclined portion.

Since water that has entered the space between the back surface of the case and the attachment surface can fall on the drainage space and flow into the drainage port along the inclined portion of the lower wall, the amount of water coming into contact with the tube portion coupled to the inclined portion can be suppressed, thus making it possible to more reliably avoid situations where the head portion surrounded by the tube portion is wetted. In addition, the inclined portion is reinforced by the tube portion. Furthermore, the space between the lower end of the back surface of the first case and the inclined portion can be effectively utilized as a region in which the tube portion is installed.

(6) In the electrical junction box according to any one of (1) to (5) above, it is preferable that the case includes a first case having the back surface, and a second case configured to be fixed to the first case, the second case includes a peripheral surface portion configured to cover an outer periphery of the first case, the peripheral surface portion includes an upper edge portion above the back surface, a groove portion extending in a left-right direction and having laterally opposite ends that are respectively open on laterally outer surfaces of the peripheral surface portion is provided on a surface of the upper edge portion that opposes the attachment surface, and the groove portion is provided with an upper end inclined surface portion that is inclined downward toward the laterally opposite ends.

When the case is attached to the attachment surface in the vertical orientation, part of water that has entered the space between the upper end of the case and the attachment surface flows along the groove portion and is discharged outward in the left-right direction from the upper end inclined surface portion. Accordingly, water can be prevented from falling down to the water receiving port, thus making it possible to reduce the amount of water entering the drainage space.

Specific examples of the present disclosure will be described below with reference to the drawings. It should be noted that the present disclosure is not limited to these examples, and is intended to include all modifications which fall within the scope of the claims and the meaning and scope of equivalents thereof.

### Embodiment 1

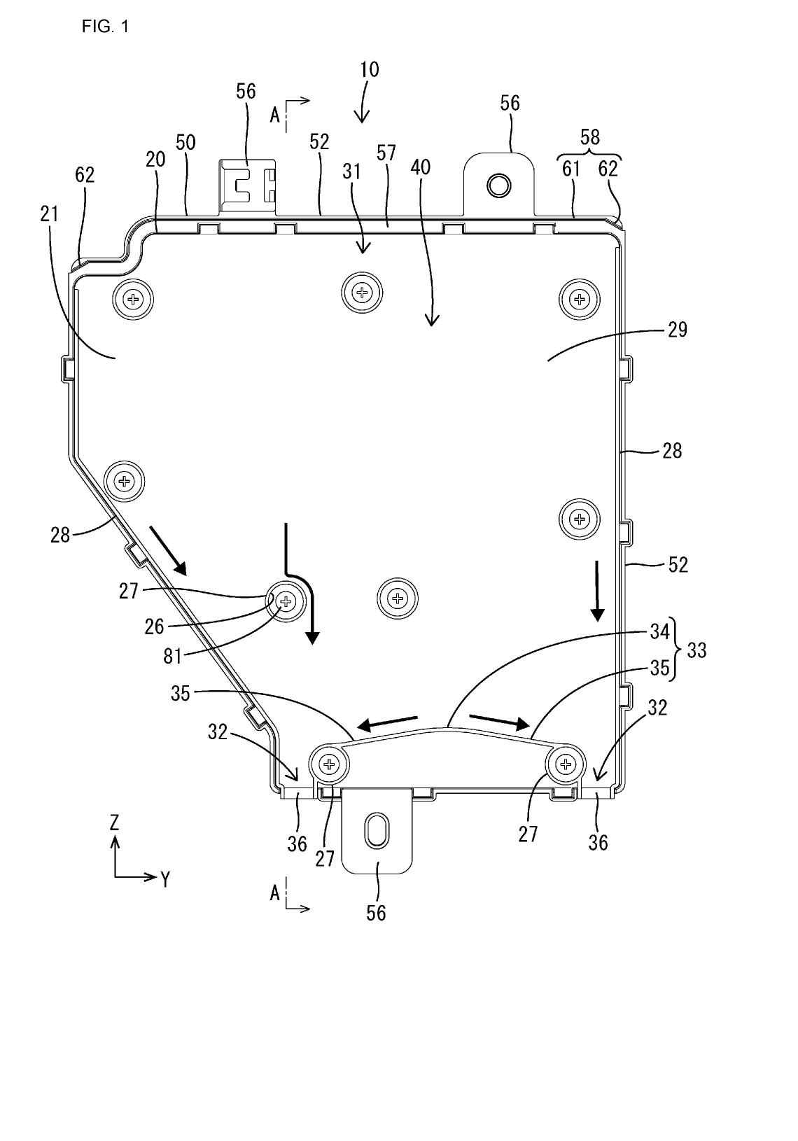

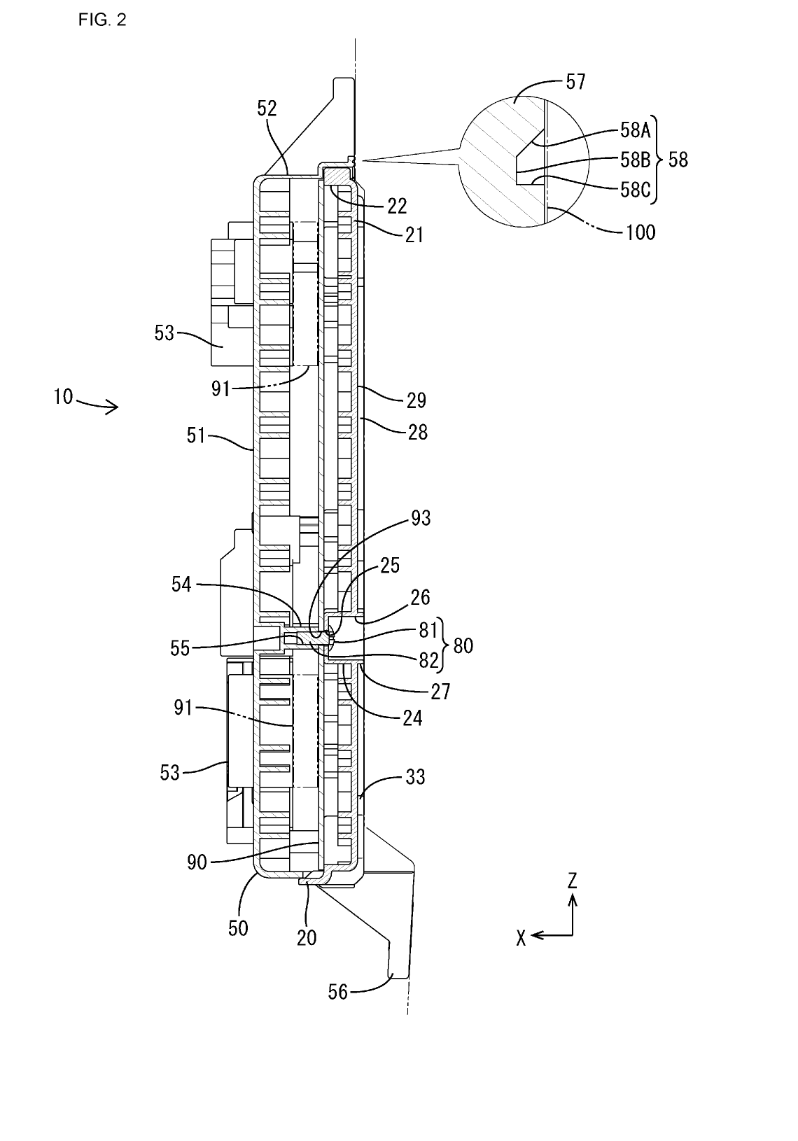

As shown in FIGS. 1 to 4, an electrical junction box 10 according to Embodiment 1 includes a case 20, 50 having an overall flat box shape. The case is made up of a first case 20 and a second case 50. The electrical junction box 10 accommodates a substrate 90 between the first case 20 and the second case 50. Here, the substrate 90 is a rigid printed circuit board on which a plurality of electronic components 91 (shown simplified in FIG. 2) are mounted. The electrical junction box 10 is attached, in a vertical orientation in which the longitudinal direction thereof is oriented in the up-down direction, to an attachment surface 100 of a vehicle. Reference characters X, Y, and Z in FIGS. 1 and 2 represent a front-rear direction, a left-right direction, and an up-down direction, respectively, in Embodiment 1. The reference directions are provided for the sake of convenience. In principle, when the electrical junction box 10 in the vertical orientation is viewed from the front or the rear, a surface that is distant from the center of the case 20, 50, and a shape of the surface are referred to as an "outer peripheral surface" and an "outer periphery", respectively, and a direction in which the "outer peripheral surface" is oriented is referred to as "outward".

### Second Case 50

The second case 50 is made of synthetic resin. The second case 50 is made of a material having high heat resistance and high dimensional stability in order to prevent warping of hood portions 53 described below. For example, the second case 50 is an amorphous thermoplastic resin, and is made of a modified polyphenylene ether (PPE) resin having a glass transition temperature of 200°C or more. The second case 50 of Embodiment 1 is made of a material in which a PPE resin is mixed with a polystyrene (PS) resin with which a reinforcing material such as glass fibers is blended in an amount of about 20%.

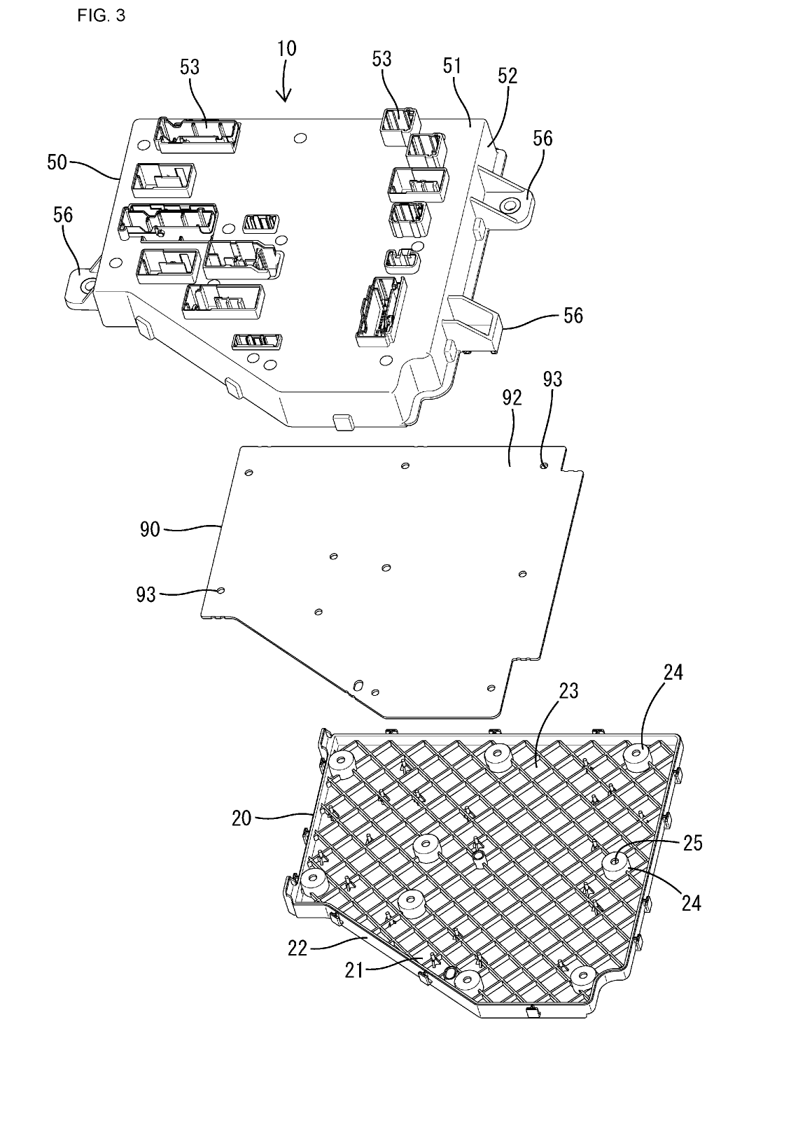

As shown in FIGS. 2 and 3, the second case 50 is a cover case configured to cover a mounting surface 92 of the substrate 90 on which the electronic components 91 are mounted. The second case 50 includes a flat plate-shaped surface portion 51 whose plate surface is oriented in the front-rear direction, and a peripheral surface portion 52 protruding rearward from the outer periphery of the surface portion 51. The outer periphery of the surface portion 51 has a shape conforming to the outer shape of the substrate 90. A plurality of hood portions 53 protrude from a front surface (a surface opposite to a surface opposing the mounting surface 92) of the surface portion 51. Each of the hood portions 53 has a tubular shape, and penetrates the surface portion 51 in the front-rear direction. Connectors of the electronic components 91 mounted on the substrate 90 are fitted inside the respective corresponding hood portions 53, and tabs of terminals (not shown) attached to the connectors protrude therefrom.

As shown in FIG. 2, a plurality of receiving tube portions 54 (only one of which is shown in FIG. 2) protrude from a rear surface (a surface opposing the mounting surface 92) of the surface portion 51. Each of the receiving tube portions 54 is provided with a fixing hole 55. A fixing member 80 for coupling the first case 20 and the second case 50 to each other is fixed to the fixing hole 55 of each of the receiving tube portions 54 by screwing or the like. Although the fixing members 80 of Embodiment 1 are screws, other fixing members such as bolts and pins can also be used.

The peripheral surface portion 52 is coupled to the surface portion 51 over the entire outer periphery thereof. The outer peripheral surface of the peripheral surface portion 52 is disposed along the front-rear direction. As shown in FIG. 3, a plurality of attachment fixing portions 56 protrude outward from the outer peripheral surface of the peripheral surface portion 52. In the case of Embodiment 1, two attachment fixing portions 56 protrude upward from positions on an upper surface of the peripheral surface portion 52 that are spaced apart in the left-right direction, and one attachment fixing portion 56 protrudes rearward and downward from a position near one of left and right sides of a lower surface of the peripheral surface portion 52. In a state of the case 20, 50 in which the second case 50 is coupled to the first case 20, the second case 50 is attached and fixed to the attachment surface 100 via attachment members (not shown) such as bolts configured to be engaged with the attachment fixing portions 56.

As shown in FIG. 1, the peripheral surface portion 52 includes a flange-shaped upper edge portion 57 projecting outward (upward) from a rear end of the upper surface thereof. As shown in FIG. 2, a rear surface of the upper edge portion 57 opposes the attachment surface 100 and is disposed along the up-down direction and the left-right direction. A groove portion 58 is formed on the rear surface of the upper edge portion 57. As shown in FIG. 1, the groove portion 58 includes a horizontal portion 61 extending in an elongated manner in the left-right direction on an underside surface of the upper edge portion 57, and upper end inclined surface portions 62 that are inclined downward toward laterally opposite ends from positions located on laterally outer sides of the horizontal portion 61. A cross section of the groove portion 58 that intersects the extension direction thereof has a recessed shape. As shown in FIG. 2, the cross section of the groove portion 58 is made up of an upper surface 58A that is inclined downward toward the front, an inner surface 58B disposed along the up-down direction, and a lower surface 58C disposed along the front-rear direction.

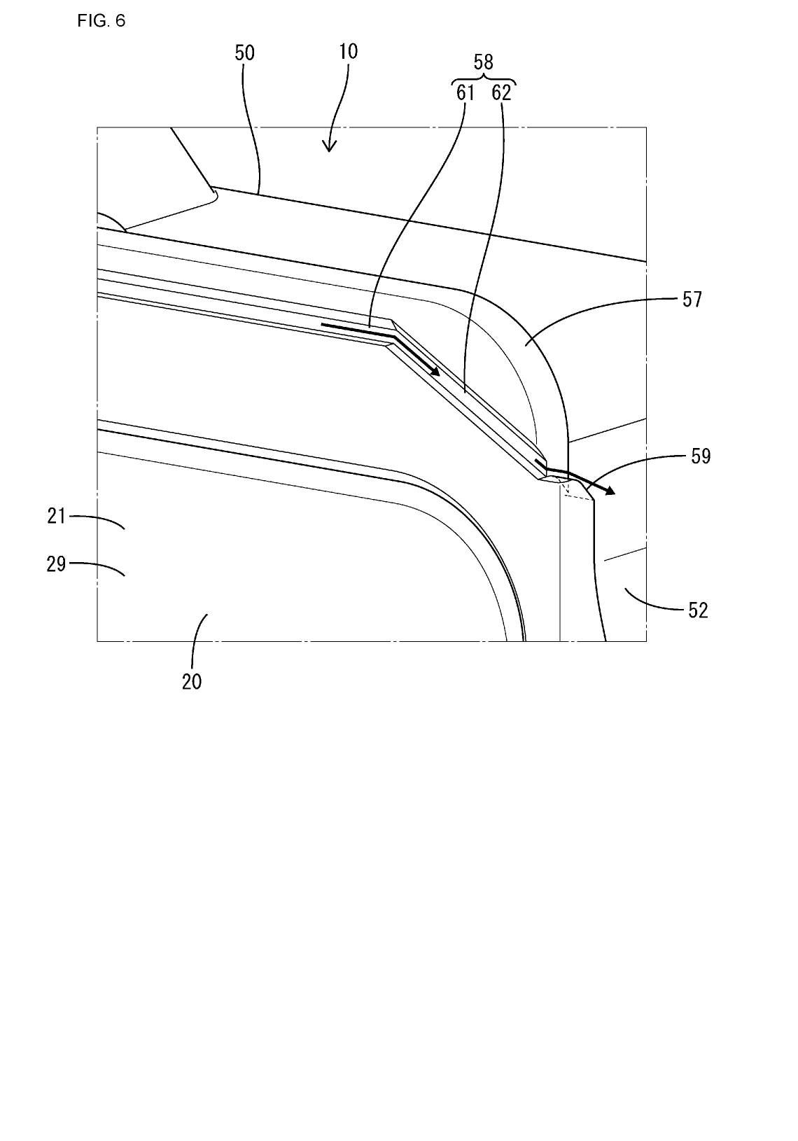

As shown in FIG. 6, laterally opposite ends of the upper end inclined surface portion 62 of the groove portion 58 are respectively open on laterally outer surfaces (surfaces directed outward in the left-right direction) of the upper edge portion 57. A side end inclined surface portion 59 extending forward and downward so as to be continuous from the upper end inclined surface portion 62 is provided on each of the laterally outer surfaces of the upper edge portion 57. The side end inclined surface portions 59 are open above and in front of the peripheral surface portion 52.

### First Case 20

The first case 20 is made of synthetic resin. The first case 20 is made of a strong material having high mechanical strength such as impact resistance in order to prevent the substrate 90 from sinking when the connectors of the electronic components 91 are fitted inside the hood portions 53. For example, the first case 20 is made of a material obtained by adding a reinforcing material such as glass fibers to a thermoplastic resin and having an impact strength (Izod with Notch) of 40 J/m or more. In the case of Embodiment 1, the first case 20 is made of a material in which a polybutylene terephthalate (PBT) resin is mixed with a reinforcing material such as glass fibers in an amount of about 30%. Accordingly, the first case 20 and the second case 50 according to Embodiment 1 are made of different kinds of materials.

As shown in FIGS. 2 and 3, the first case 20 is a cover case configured to cover a surface of the substrate 90 that is located opposite to the mounting surface 92. The first case 20 includes a flat plate-shaped underside surface portion 21 whose plate surface is oriented in the front-rear direction, and an outer peripheral edge portion 22 protruding forward from the outer periphery of the underside surface portion 21. The outer periphery of the underside surface portion 21 has a shape that is one size smaller than that of the surface portion 51 and conforms to the outer shape of the substrate 90.

A front surface of the underside surface portion 21 opposes an underside surface of the substrate 90 that is located opposite to the mounting surface 92. As shown in FIG. 3, a grid-patterned rib 23 extending in an oblique direction that intersects the up-down direction and the left-right direction protrudes from the front surface of the underside surface portion 21. The first case 20 is reinforced by the rib 23. In addition, a plurality of counterbored tube portions 24 protrude from the front surface of the underside surface portion 21. Each of the counterbored tube portions 24 has a cylindrical shape, and has, at the center of the front surface portion thereof, a passage hole 25 through which a shaft portion 82 of a fixing member 80 is passed. As shown in FIG. 2, each of the counterbored tube portions 24 has a countersunk hole 26 that is open in the rear surface (a back surface 29 described below) of the underside surface portion 21. A head portion 81 of a fixing member 80 is accommodated in the countersunk hole 26. The counterbored tube portions 24 and the respective corresponding receiving tube portions 54 are disposed so as to oppose each other with the substrate 90 interposed therebetween. The shaft portions 82 of the fixing members 80 are inserted into the fixing holes 55 of the receiving tube portions 54 from the passage holes 25 of the counterbored tube portions 24 through the through holes 93 of the substrate 90.

The outer peripheral edge portion 22 is coupled to the underside surface portion 21 over the entire outer periphery thereof. The outer peripheral edge portion 22 is fitted to the peripheral surface portion 52. The outer peripheral surface of the outer peripheral edge portion 22 is covered by the peripheral surface portion 52. The outer periphery of the underside surface of the substrate 90 is disposed so as to be held along a front end of the outer peripheral edge portion 22.

The rear surface of the underside surface portion 21 constitutes a back surface 29 that opposes the attachment surface 100, and is disposed along the up-down direction and the left-right direction. As shown in FIG. 1, tube portions 27 protruding rearward from the outer periphery of the countersunk holes 26 are provided on the back surface 29 of the underside surface portion 21. Each of the tube portions 27 is in the form of a cylinder or an annular ring-shaped rib, and protrudes from the outer periphery of the corresponding countersunk hole 26 over the entire periphery thereof. As shown in FIG. 2, each of the tube portions 27 is integrally continuous with the corresponding counterbored tube portion 24 with the underside surface portion 21 interposed therebetween. Each of the passage holes 25 is located at the center of the countersunk hole 26 of the corresponding tube portion 27 in a rear view.

As shown in FIG. 1, the first case 20 has left and right side walls 28 protruding rearward from two positions on the back surface 29 of the underside surface portion 21 that are spaced apart in the left-right direction, and extending in the up-down direction as a whole. In the case of Embodiment 1, the side walls 28 extend in the form of ribs at opposite ends of the back surface 29 of the underside surface portion 21 in the left-right direction so as to rim the opposite ends from upper ends to lower ends thereof. Of the side walls 28, the side wall 28 located at one of laterally opposite ends (the left end in FIG. 1) includes a portion extending straight downward from an upper end thereof, and a portion extending from an intermediate position thereof toward the lower end while being inclined toward the center in the left-right direction. The side wall 28 located at the other of the laterally opposite ends (the right end in FIG. 1) extends from an upper end thereof toward a lower end thereof so as to hang downward as a whole.

One water receiving port 31 that is open above the back surface 29 is provided between the upper ends of the side walls 28. The water receiving port 31 is located near an upper end of the first case 20, and is widely open with an opening width close to the entire width of the first case 20 in the left-right direction. Two drainage ports 32 that are open below the back surface 29 are provided between the lower ends of the side walls 28. Each of the drainage ports 32 is located at a lower end of the first case 20, and is narrowly open with an opening width on the order of the diameter of the tube portions 27 on laterally outer sides, respectively, with the lower wall 33 interposed therebetween. Even the total opening width of the drainage ports 32 is sufficiently smaller than the opening width of the water receiving port 31. The attachment fixing portion 56 protruding from the lower surface of the peripheral surface portion 52 of the second case 50 is located between the drainage ports 32 in the left-right direction.

The first case 20 has a lower wall 33 protruding rearward from a position near a lower end of the back surface 29 of the underside surface portion 21 and extending in the left-right direction as a whole. Opposite ends of the lower wall 33 in the left-right direction are respectively coupled to the tube portions 27 at the lowermost end that are paired in the left-right direction. The drainage ports 32 are defined between the tube portions 27 at the lowermost end and the respective corresponding side walls 28. The lower wall 33 has a mountain-like shape in a rear view, and includes a top portion 34 located at an intermediate portion thereof in the left-right direction, and an inclined portion 35 that is gently inclined downward from the top portion 34 toward the opposite ends in the left-right direction. The opposite ends of the inclined portion 35 in the left-right direction are coupled to the respective corresponding tube portions 27 at the lowermost end, and are continuously inclined downward along outer peripheral arcs of the tube portions 27. Note that, as shown in FIG. 2, the respective rear ends of the tube portions 27, the side walls 28, and the lower wall 33 are disposed at the same position in the front-rear direction.

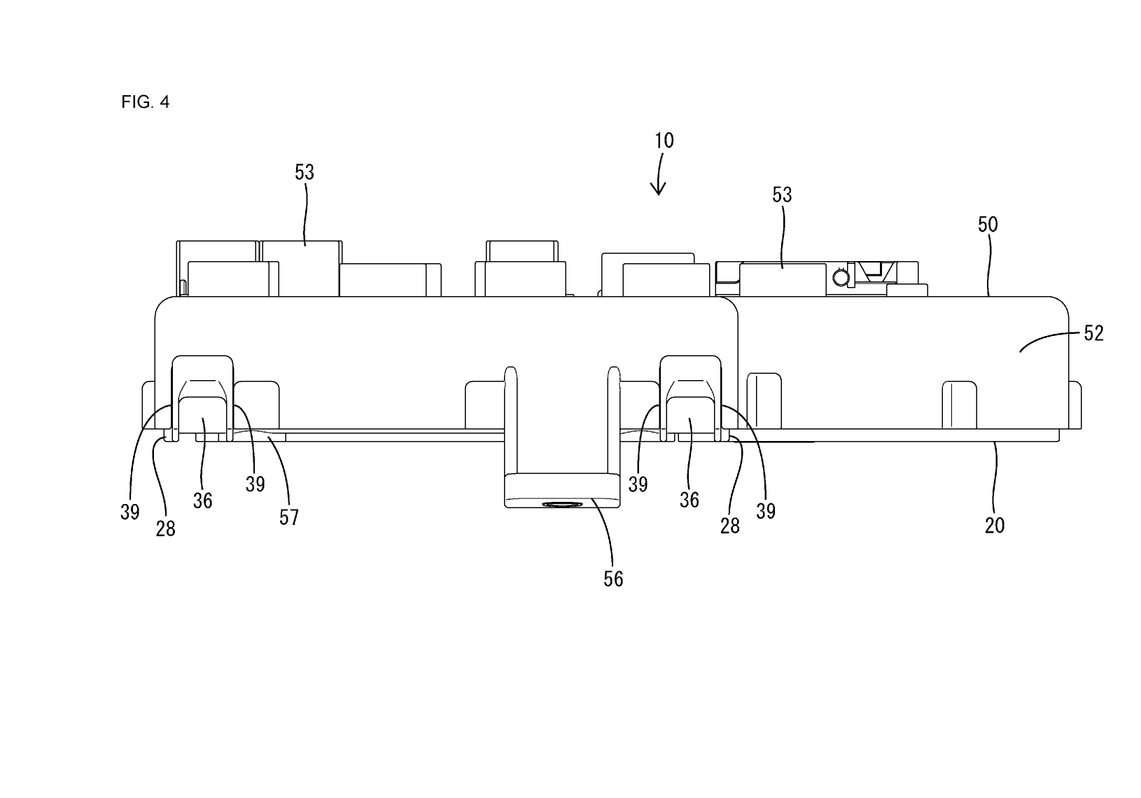

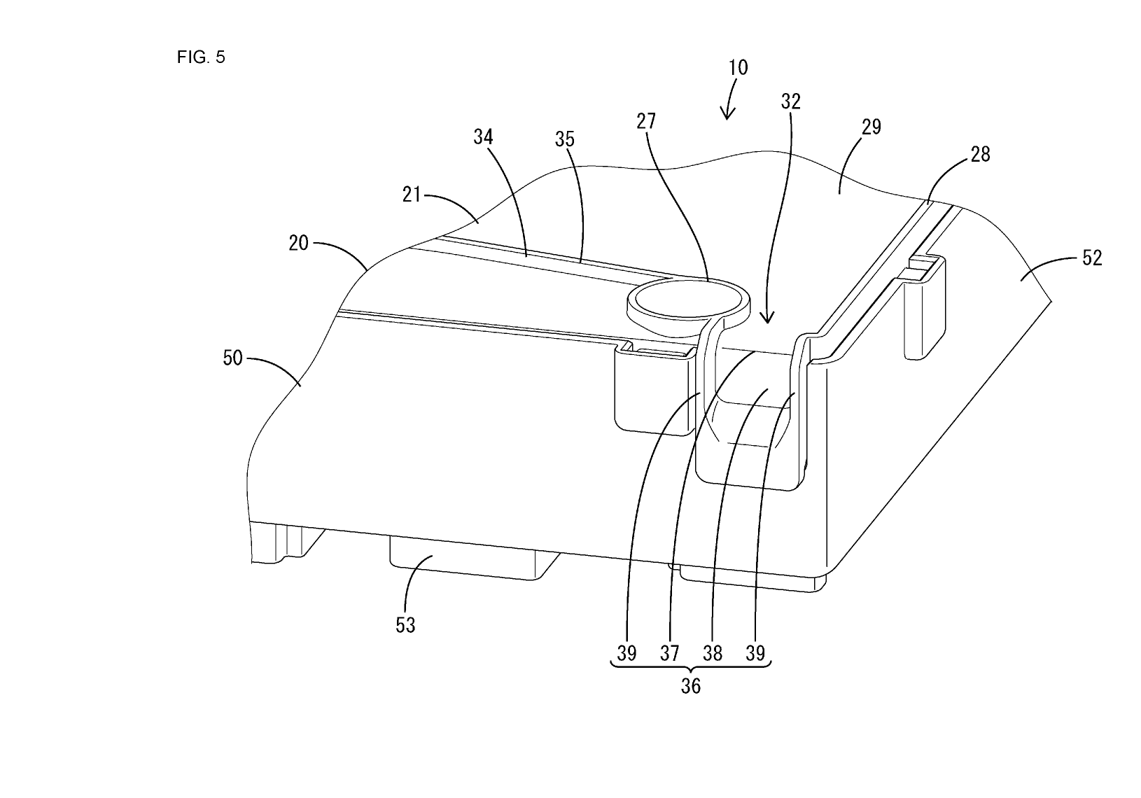

Drainage guide portions 36 are provided at the lower end of the first case 20. As shown in FIG. 1, a pair of drainage guide portions 36 are provided at positions between the tube portions 27 at the lowermost end and the respective corresponding side walls 28 at laterally opposite end portions at the lower end of the first case 20. As shown in FIGS. 4 and 5, each of the drainage guide portions 36 has the shape of a protruding piece protruding from the lower end of the underside surface portion 21. Specifically, the drainage guide portions 36 protrude downward with a short length from the lower end of the underside surface portion 21 and then extend forward with a long length. A forward extending portion of each of the drainage guide portions 36 is disposed along the lower surface of the peripheral surface portion 52 so as to cover the lower surface of the peripheral surface portion 52. The drainage guide portions 36 extend across a boundary between the outer peripheral surface of the first case 20 and the peripheral surface portion 52, from the underside surface portion 21 toward the lower side of the peripheral surface portion 52. A bent portion (curved portion) at a rear end of each of the drainage guide portions 36 is disposed so as to fill a gap formed at the above-described boundary.

As shown in FIG. 5, each of the drainage guide portions 36 includes a drainage channel surface 38 extending with the same width in the left-right direction, from a curved surface 37 that is curved and continuous with the back surface 29 of the underside surface portion 21 toward a lower surface thereof extending forward. The drainage port 32 is provided above the drainage channel surface 38 of the drainage guide portion 36.

Rib-shaped guide rail portions 39 extending along the extension direction of each of the drainage guide portions 36 protrude from laterally opposite ends of the drainage guide portion 36. A pair of lateral guide rail portions 39 are provided, with the drainage channel surface 38 interposed therebetween. Of the guide rail portions 39, the guide rail portion 39 located laterally outward is coupled to the corresponding side wall 28 and is curved and extends forward from the coupled portion, and the guide rail portion 39 located laterally inward is coupled to the corresponding tube portion 27 of the lowermost end, and is curved and extends forward from the coupled portion. The opening width of the drainage ports 32 in the left-right direction is defined by the guide rail portions 39.

### Drainage Route of Electrical Junction Box 10

Next, a drainage route used when the electrical junction box 10 is wetted will be described.

As shown in FIG. 2, the electrical junction box 10 is disposed in the vertical orientation, and is fixed to the attachment surface 100 of the vehicle in a state in which the back surface 29 of the underside surface portion 21 opposes (faces) the attachment surface 100. At this time, the respective rear ends of the lower wall 33, the side walls 28, and the tube portions 27 are disposed close to the attachment surface 100 so as to be contactable therewith. A drainage space 40 (see FIG. 1) that is in communication with the water receiving port 31 and the drainage ports 32 is formed between the back surface 29 of the underside surface portion 21 and the attachment surface 100.

In use of the electrical junction box 10, for example, when water splashes to the case 20, 50 from above and enters a space between the first case 20 and the attachment surface 100, the water first enters the groove portion 58 of the upper edge portion 57 and flows on the horizontal portion 61 of the groove portion 58 in the left-right direction. Furthermore, the water flows from the upper end inclined surface portions 62 through the side end inclined surface portions 59, and is primarily discharged to the outside of the case 20, 50 (see the thick lines in FIG. 6). Accordingly, part of the water flows on the groove portion 58, and thus is discharged in advance to the outside of the case 20, 50 without entering the drainage space 40 from the water receiving port 31.

The water that has passed through the groove portion 58 enters the drainage space 40 formed between the back surface 29 of the underside surface portion 21 and the attachment surface 100 from the water receiving port 31, and flows down along the back surface 29 of the underside surface portion 21. The water can fall while being guided along the side walls 28 on the laterally outer sides (opposite ends and near the opposite ends) of the back surface 29 of the underside surface portion 21 (see the left and right thick lines in FIG. 1). Accordingly, it is possible to prevent the water from entering a gap that may be formed at a boundary between the outer peripheral surface of the first case 20 and the peripheral surface portion 52 at the laterally opposite ends of the case 20, 50.

In addition, part of the water can come into contact with the tube portions 27 (except for the tube portions 27 at the lowermost end) en route, and flows down along the outer peripheral arcs of the tube portions 27 so as to flow around the tube portions 27 (see the thick line near the lateral center in FIG. 1). Accordingly, it is possible to prevent the water from entering the countersunk holes 26 of the tube portions 27, and thus to prevent situations where the head portions 81 of the fixing members 80 are wetted.

Water falling on a laterally inner side (the center and near the center) of the drainage space 40 can come into contact with the lower wall 33 at a position near the lower end of the back surface 29 of the underside surface portion 21, then fall down along the inclined portions 35 so as to be laterally separated via the top portion 34, and reach the drainage ports 32 (see the thick lines on the lower side of FIG. 1). The water falling on the laterally outer sides of the drainage space 40 can fall along the side walls 28, and directly reach the drainage ports 32. In this manner, the water that has merged in the left and right drainage ports 32 flows on the drainage channel surface 38 of the drainage guide portion 36 while being guided by the left and right guide rail portions 39, and further falls downward from the drainage ports 32 and is discharged.

As described thus far, the electrical junction box 10 according to Embodiment 1 includes the case 20, 50 configured to accommodate the substrate 90 on which the electronic components 91 are mounted. The case 20, 50 has, on the surface thereof opposite to the surface thereof opposing the substrate 90, the back surface 29 facing the attachment surface 100. The case 20, 50 has, in the vertical orientation in which the back surface 29 is disposed along the up-down direction, the left and right side walls 28 protruding from the positions of the back surface 29 that are spaced apart in the left-right direction and extending from the upper ends thereof toward the lower ends thereof. The water receiving port 31 that is open above the back surface 29 is provided between the upper ends of the left and right side walls 28. The drainage ports 32 that are open below the back surface 29 are provided between the lower ends of the left and right side walls 28.

When the case 20, 50 is attached to the attachment surface 100 in the vertical orientation, the drainage space 40 is formed between the back surface 29 of the case 20, 50 and the attachment surface 100 by the side walls 28 interposed between the two surfaces 29 and 100. When water enters the space between the back surface 29 of the case 20, 50 and the attachment surface 100 from the water receiving port 31, the entered water is promptly discharged below the case 20, 50 from the drainage space 40 through the drainage ports 32. Accordingly, it is possible to avoid situations where a problem occurs as a result of water residing between the back surface 29 of the case 20, 50 and the attachment surface 100.

The case 20, 50 has the lower wall 33 protruding from a position near the lower end of the back surface 29 and extending in a direction intersecting the extension direction of the left and right side walls 28. The lower wall 33 includes the inclined portions 35 that are inclined downward toward the respective corresponding drainage ports 32. With this configuration, water that has entered the space between the back surface 29 of the case 20, 50 and the attachment surface 100 falls on the drainage space 40 to come into contact with the lower wall 33, and is further guided to the drainage ports 32 along the inclined portions 35 of the lower wall 33. Accordingly, it is possible to prevent water from remaining at positions near the lower end of the back surface 29.

The case includes the first case 20 having the back surface 29, and the second case 50 configured to be fixed to the first case 20. The second case 50 includes the peripheral surface portion 52 configured to cover the outer periphery of the first case 20. The drainage ports 32 are provided at the respective corresponding drainage guide portions 36 extending below the peripheral surface portion 52, across the boundary between the lower end of the first case 20 and the peripheral surface portion 52. With this configuration, the water in the drainage ports 32 can flow along the drainage guide portions 36, thus making it possible to prevent situations where water enters the interior of the case 20, 50 from the boundary between the lower end of the first case 20 and the peripheral surface portion 52.

The first case 20 has the countersunk holes 26 that are open in the back surface 29 to accommodate the head portions 81 of the fixing members 80, and the tube portions 27 protruding from the outer peripheries of the countersunk holes 26 in the back surface 29. With this configuration, water that has entered the space between the back surface 29 of the first case 20 and the attachment surface 100 can flow down while coming into contact with the tube portions 27 and flowing around the tube portions 27. Accordingly, it is possible to avoid situations where the head portions 81 of the fixing members 80 are wetted.

Furthermore, the tube portions 27 at the lowermost end are located between the lower end of the back surface 29 of the first case 20 and the respective corresponding inclined portions 35, and are coupled to the inclined portions 35. With this configuration, the amount of water coming into contact with the tube portions 27 at the lowermost end can be suppressed, thus making it possible to more reliably avoid situations where the head portions 81 surrounded by the tube portions 27 are wetted. In addition, the inclined portions 35 are reinforced by the tube portions 27. Furthermore, the space between the lower end of the back surface 29 of the first case 20 and the inclined portions 35 can be effectively utilized as a region in which the tube portions 27 are installed.

Furthermore, the peripheral surface portion 52 of the second case 50 includes the upper edge portion 57 above the back surface 29. The groove portion 58 extending in the left-right direction and having laterally opposite ends that are respectively open on laterally outer surfaces of the peripheral surface portion 52 are provided on the surface of the upper edge portion 57 that opposes the attachment surface 100. The groove portion 58 is provided with the upper end inclined surface portions 62 that are inclined downward toward the laterally opposite ends. With this configuration, part of water that has entered the space between the upper end of the case 20, 50 and the attachment surface 100 flows along the groove portion 58 and is discharged outward in the left-right direction from the upper end inclined surface portions 62. Accordingly, water can be prevented from falling down to the water receiving port 31, thus making it possible to reduce the amount of water entering the drainage space 40.

### Other Embodiments of the Present Disclosure

It should be appreciated that Embodiment 1 presently disclosed is in all respects illustrative and not limiting.

In the case of Embodiment 1 described above, the left and right side walls are disposed at the laterally opposite ends of the back surface of the underside surface portion. In contrast, according to other embodiments, the left and right side walls need only be disposed at positions on the back surface of the underside surface portion that are spaced apart in the left-right direction, and may be disposed, for example, laterally inward of the laterally opposite ends of the back surface. Three or more side walls may protrude from the back surface of the underside surface portion.

In the case of Embodiment 1 described above, an attachment mode in which the electrical junction box is fixed to the attachment surface in the vertical orientation is assumed. However, according to the present disclosure, the attachment mode of the electrical junction box is not limited to the vertical orientation.

What is claimed is:

1. An electrical junction box comprising:
a case configured to accommodate a substrate on which an electronic component is mounted, wherein
the case has, on a surface thereof opposite to a surface thereof opposing the substrate, a back surface facing an attachment surface,
the case has, in a vertical orientation in which the back surface is disposed along an up-down direction, left and right side walls protruding from positions of the back surface that are spaced apart in a left-right direction and extending from upper ends thereof toward lower ends thereof,
a water receiving port that is open above the back surface is provided between the upper ends of the left and right side walls, and
a drainage port that is open below the back surface is provided between the lower ends of the left and right side walls.

2. The electrical junction box according to claim 1, wherein the case has a lower wall protruding from a position near a lower end of the back surface and extending in a direction intersecting an extension direction of the left and right side walls, and
the lower wall includes an inclined portion that is inclined downward toward the drainage port.

3. The electrical junction box according to claim 1, wherein the case includes a first case having the back surface, and a second case configured to be fixed to the first case,
the second case includes a peripheral surface portion configured to cover an outer periphery of the first case, and
the drainage port is provided at a drainage guide portion extending below the peripheral surface portion, across a boundary between a lower end of the first case and the peripheral surface portion.

4. The electrical junction box according to claim 1, wherein the case includes a first case having the back surface, and a second case configured to be fixed to the first case via a fixing member, and
the first case has a countersunk hole that is open in the back surface to accommodate a head portion of the fixing member, and a tube portion protruding from an outer periphery of the countersunk hole in the back surface.

5. The electrical junction box according to claim 2, wherein the case includes a first case having the back surface, and a second case configured to be fixed to the first case via a fixing member,
the first case has a countersunk hole that is open in the back surface to accommodate a head portion of the fixing member, and a tube portion protruding from an outer periphery of the countersunk hole in the back surface, and
the tube portion is located between a lower end of the back surface of the first case and the inclined portion, and is coupled to the inclined portion.

6. The electrical junction box according to claim 1, wherein the case includes a first case having the back surface, and a second case configured to be fixed to the first case,
the second case includes a peripheral surface portion configured to cover an outer periphery of the first case,
the peripheral surface portion includes an upper edge portion above the back surface,
a groove portion extending in a left-right direction and having laterally opposite ends that are respectively open on laterally outer surfaces of the peripheral surface portion is provided on a surface of the upper edge portion that opposes the attachment surface, and
the groove portion is provided with an upper end inclined surface portion that is inclined downward toward the laterally opposite ends.
